(19) United States
(12) Patent Application Publication
(10) Pub. No.: US 2013/0327926 A1
(43) Pub. Date: Dec. 12, 2013

(54) FPA MODULE FOR OBTAINING 3-DIMENSIONAL IMAGE

(71) Applicant: Electronics and Telecommunications Research Institute, Daejeon (KR)

(72) Inventors: Yong Hwan Kwon, Daejeon (KR); Bongki Mheen, Daejeon (KR); Myoung Sook Oh, Daejeon (KR); Jae Sik Sim, Daejeon (KR); Ki Soo Kim, Daejeon (KR); Eun Soo Nam, Daejeon (KR)

(21) Appl. No.: 13/915,140

(22) Filed: Jun. 11, 2013

(30) Foreign Application Priority Data
Jun. 12, 2012 (KR) 10-2012-0062568
May 7, 2013 (KR) 10-2013-0051216

(51) Int. Cl. H01L 27/146

(52) U.S. Cl. CPC H01L 27/146
USPC 250/208.1

(57) ABSTRACT

Provided is an FPA module capable of further improving a quality of an obtained 3-dimensional image by adjusting an interval of an arrangement of optical detectors and a size of the optical detector within an FPA module for obtaining the 3-dimensional image. An FPA module for obtaining a 3-dimensional image according to an exemplary embodiment of the present disclosure includes a plurality of light detectors configured to detect light reflected from a monitoring target, in which the plurality of light detectors is disposed at different intervals according to positions.

### CROSS-REFERENCE TO RELATED APPLICATIONS

This application is based on and claims priority from Korean Patent Application No. 10-2012-0062568, file on Jun. 12, 2012, and Korean Patent Application No. 10-2013-0051216, filed on May 7, 2013, with the Korean Intellectual Property Office, the disclosure of which is incorporated herein in its entirety by reference.

### TECHNICAL FIELD

The present disclosure relates to a focal plane array (FPA) module used in an electronic device for obtaining a 3-dimensional image, and more particularly, to a technology of adjusting an interval between detectors and a size of the detector within an FPA module.

### BACKGROUND

A 3-dimensional image technology is widely used for obtaining an image of a distant military target, obtaining an image for a natural environment for surveilling a landslide, and the like, and obtaining an image necessary for driving of an unmanned autonomous travelling vehicle, as we as a display product, such as a 3D TV. Recently, according to recent further expansion of an application area of the 3-dimensional image, a technology capable of obtaining a 3-dimensional image having an excellent quality in various environments has been demanded.

The obtainment of a 3-dimensional image in an application, such as light detection and ranging (LIDAR) or laser detection and ranging (LADAR), may be implemented by various methods, such as a method of measuring a delay time of flight of a reflected wave of light, and a method of obtaining reflection information by using a characteristic difference between a modulated and returned signal when an optical signal is transmitted and a signal output at that time. The first method is not a method of obtaining a reflected wave of a modulated optical signal, so that the first method has been widely used because a measurable range may be very widely set and recognition of a pulse is simple. The second method demands a more complex system than that of the first method and has a limitation of a measurement distance according to a modulation characteristic, but may have a higher signal to noise ratio (SNR) characteristic, so that the second method has been used in partial necessary fields. A commonly confronted problem of the 3-dimensional image obtaining technologies by various methods is that it is not easy to obtain a dynamic range of an image. In a case where a dynamic range, that is, an optical intensity difference between the brightest place and a dark place, is not a maximal value in an image, it is difficult to discriminate an object at a bright place due to excessive brightness, and it is difficult to discriminate an object at a dark place due to excessive darkness. In a case where a dynamic range is not secured, an image for a partial region is lost in a general image or a clear image may not be obtained due to a poor SNR of a corresponding portion. However, a 3-dimensional image has a problem not only in that an area failing to sufficiently secure a dynamic range exhibits a simple image loss or a decrease in an SNR of a corresponding portion, but also in that a form of an image which needs to be secured, is lost.

Especially, since a place requiring a 3-dimensional image may include a case in which an optical signal of a bright background, such as sun, is present, as well as an optical signal of a dark place, and light reflectivity of a reflector may also be very variously changed according to a type of a target object and a reflection angle, so that a structure of receiving a high dynamic range may be a very essential factor in such an environment.

In a case of an existing general image, an image may be obtained under various exposure conditions by adjusting an integration time or an aperture time corresponding to a time for collecting an optical signal, in addition of a method of improving a characteristic of a device, and it is less difficult to obtain an image with a high dynamic range by using the aforementioned method. That is, an image with a high dynamic range may be obtained by changing optical signals input in pixels with the comparatively same intensity according to various conditions (an aperture time, a time and a method of driving a detection device, and the like) by using the detection device having an excellent photosensitizing capability without regard to a light detection time.

In the meantime, in a case of a 3-dimensional image, in order to obtain high distance resolution, a reflected wave needs to be detected by using a very short optical signal, that is, an optical signal having a pulse width of 1 to 10 nsec, and a detection time needs to be 1 to 10 nsec, which is very short time. Accordingly, there is a problem in that the method of extending an integration time or changing a driving time of a device used in an existing general image cannot be applied.

### SUMMARY

The present disclosure has been made in an effort to provide an FPA module capable of further improving a quality of an obtained 3-dimensional image by adjusting an interval of an arrangement of optical detectors and a size of the optical detector within an FPA module for obtaining a 3-dimensional image.

An exemplary embodiment of the present disclosure provides a focal plane array (FPA) module for obtaining a 3-dimensional image, including: a plurality of light detectors configured to detect light reflected from a monitoring target, in which the plurality of light detectors is disposed at different intervals according to positions.

A region in which the plurality of light detectors may be divided into a high resolution region and a low resolution region, and an interval between the light detectors disposed in the high resolution region may be smaller than an interval between the light detectors disposed in the low resolution region.

The light detector may include: a light receiving unit configured to generate an electrical signal by receiving light; and a pad configured to transfer the electrical signal to an external readout IC. The light detector may further include a micro lens formed on the light receiving unit.

Another exemplary embodiment of the present disclosure provides a focal plane array (FPA) module for obtaining a 3-dimensional image, including: a plurality of light detectors configured to detect light reflected from a monitoring target, in which the plurality of light detectors has different sizes according to positions.

A region in which the plurality of light detectors is disposed may be divided into a high resolution region and a low resolution region, and the light detectors disposed in the high resolution region may be smaller than the light detectors disposed in the low resolution region.

According to the exemplary embodiments of the present disclosure, it is possible to further improve a quality of a 3-dimensional image for a desired portion while using readout ICs having the same complexity. Especially, since a large amount of costs is required for configuring the readout IC, there is a greatly significant advantage in that a quality of the 3-dimensional image is improved while maintaining the same complexity.

It is also possible to relatively increase a size of the light detector in a region in which an interval between pixels is increased, thereby additionally improving an SNR. That is, since sizes of bonding pads for electrically connecting a flip chip and the like are the same nearly regardless of the interval between the detectors, it is advantageously possible to improve the SNR by increasing a size of the detector by an area increased according to an increase in an interval between the detectors.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a diagram schematically illustrating a system for obtaining a 3-dimensional image by using a reflection time of an optical signal.

FIG. 2 is a diagram illustrating a configuration of a reception module in the system of FIG. 1 in more detail.

FIG. 3 is a diagram illustrating an arrangement of optical detectors within an existing FPA module in a type of one dimension (1×8).

FIG. 4 is a diagram illustrating an arrangement of optical detectors within an existing FPA module in a type of two dimensions (8×8).

FIG. 5A is a diagram illustrating an arrangement of optical detectors within an FPA module in a type of one dimension (1×8) according to an exemplary embodiment of the present disclosure.

FIG. 5B is a diagram illustrating an arrangement of optical detectors within an FPA module in a type of two dimensions (8×8) according to an exemplary embodiment of the present disclosure.

FIG. 6A is a diagram illustrating an arrangement of optical detectors within an FPA module in a type of one dimension (1×8) according to another exemplary embodiment of the present disclosure.

FIG. 6B is a diagram illustrating an arrangement of optical detectors within the FPA module in a type of two dimensions (8×8) according to another exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

The aforementioned objects, characteristics, and advantages will be described below with reference to the accompanying drawings, and thus those skilled in the art to which the present disclosure pertains will easily implement the technical spirit of the present disclosure. In the following description, a detailed explanation of known related functions and constitutions may be omitted so as to avoid unnecessarily obscuring the subject manner of the present disclosure. Hereinafter, an exemplary embodiment according to the present disclosure will be described with reference to the accompanying drawings in detail.

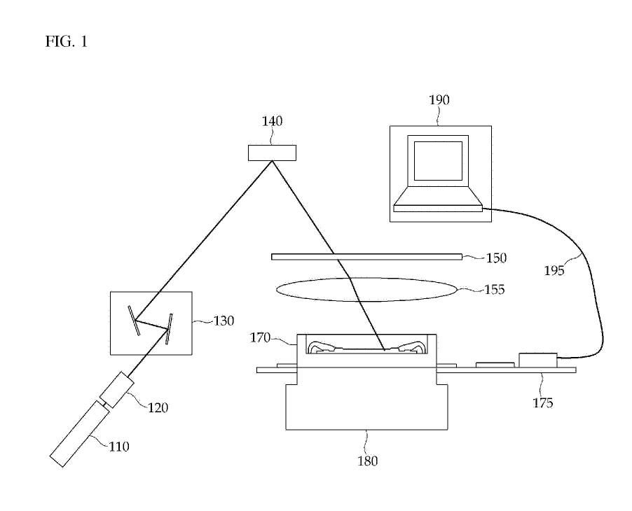

FIG. 1 is a diagram schematically illustrating a system for obtaining a 3-dimensional image by using a reflection time of an optical signal.

First, laser emitted from a pulse laser 110 for measuring a distance is output through a light transmitting optical system 120. The light emitted from the light transmitting optical system is irradiated to a desired region through an optical scanner 130. Here, a stepping motor, a brushless DC motor, a rotating minor, a Galvano mirror, or the like may be used as the light transmitting optical system 120. The light transmitting optical system 120 and the optical scanner 130 may be integrally implemented, or may be implemented with a changed order.

The laser light irradiated into the specific region hits a target object 140 and is returned. FIG. 1 illustrates that an optical path of light transmitting laser is different from an optical path of a light receiving laser, which is referred to as a dual axis structure, and a structure in which an optical path of light transmitting laser is the same as an optical path of light receiving laser is a single-axis or a uni-axial structure. The reflected and returned laser light passes through an optical filter 150 for blocking other noise light, and then passes a light receiving lens 155 for forming a focus and reaches a reception module 170. Here, an order of the optical filter 150 and the light receiving lens 155 may be changed.

The reception module 170 may be implemented like a heat-sink 180 for dispersing autonomously generated heat, and may include an interface board 175 for outputting generated data.

The data generated in the reception module 170 is transferred to an analysis device 190 through a connection cable 195 including various communication protocols, such as USB and Gigabit Ethernet, a final 3-dimensional image may be obtained by the analysis device 190 processing and displaying the transferred data.

In the meantime, the process of obtaining the 3-dimensional image based on an optical reflection signal has been described in FIG. 1, which may be, however, equally applied to a system for obtaining a 3-dimensional image of an optical modulation type.

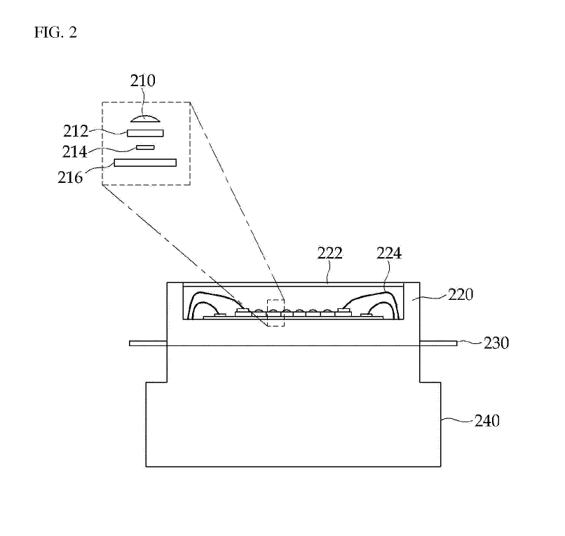

FIG. 2 is a diagram illustrating a configuration of the reception module 170 in the system of FIG. 1 in more detail.

Referring to FIG. 2, the reception module 170 includes a package module 220 capable of detecting incident light and a temperature control module 240 for controlling a temperature of a part or the entirety of the package module 220. In a case of the package module 220, performance of detecting internal moisture and the like may deteriorate according to a fall of a temperature, so that the package module 220 may be implemented as a Hermetic package. A glass film 222 for a package may be provided on an upper portion of the reception module 170, and the light entering while passing through the glass film 222 passes through a micro lens 210 and enters a light detector cell 212. In general, the light detector cell 212 is implemented in an array form, so that each light detector cell has a unique output node, and may include a flip chip connection pad 214, which is a separate package structure, so as to be connected to a readout IC (ROIC) 216 for processing the output node by utilizing a bump technology. Through the aforementioned structure, an optical signal detected by the light detector cell 212 is processed into a desired form through the ROIC 216, and a result of the processing has a structure so as to be connected through a wire bonding 224 in order to be connected to an external pin 230 of the reception module 170.

The structure of the reception module 170 suggested in FIG. 2 is a simple example, and may be implemented into variously modified forms. A method desired to be applied in the present disclosure is a method of maximizing a dynamic range of an image capable of finally obtained by the reception module 170 by changing a driving of the light detector cell 212 inside the reception module 170 according to a result of the ROIC 216.

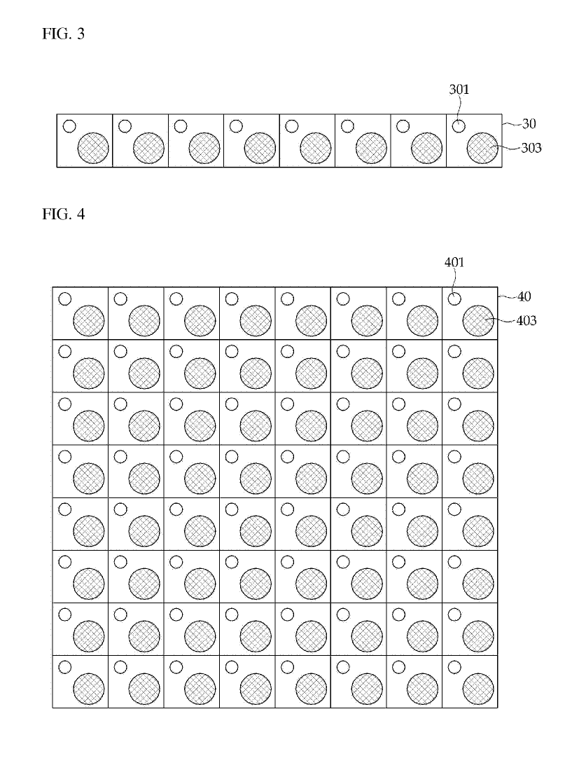

FIG. 3 is a diagram illustrating an arrangement of optical detectors within an existing FPA module in a type of one dimension (1×8). FIG. 4 is a diagram illustrating an arrangement of optical detectors within an existing FPA module in a type of two dimensions (8×8).

One detector 30 or 50 formed within the FPA module includes a light receiving unit 301 or 401 which is a region capable of receiving light, and a pad 303 or 403 for transferring an electrical signal to an external Readout IC. A micro lens (not illustrated in the drawing) may be further formed on the light receiving unit 301 or 401 in order to improve light efficiency.

As illustrated in FIGS. 3 and 4, the light detectors within the FPA module in the related art have the same size and the same interval.

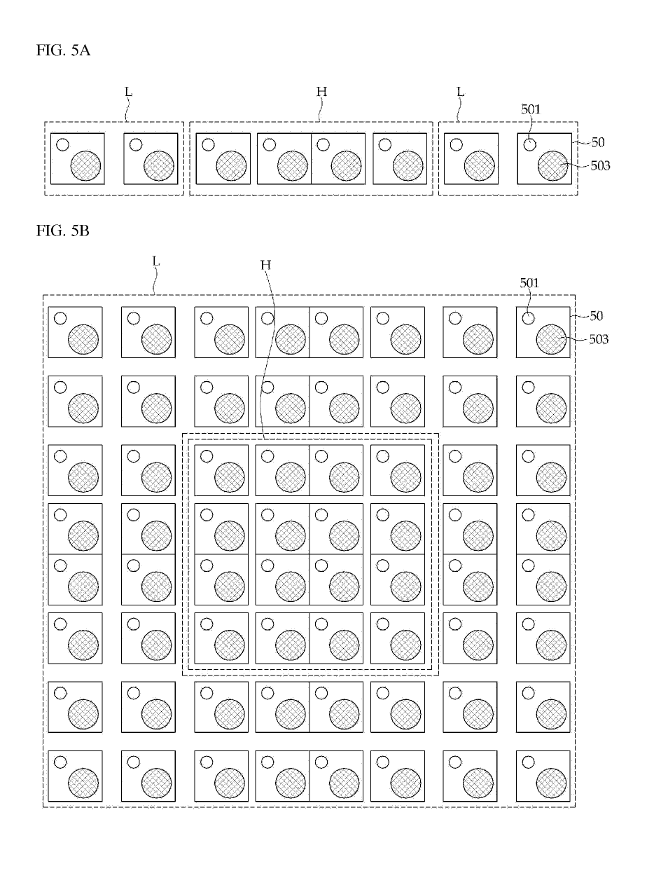

FIG. 5A is a diagram illustrating an arrangement of optical detectors within an FPA module in a type of one dimension (1×8) according to an exemplary embodiment of the present disclosure. FIG. 5B is a diagram illustrating an arrangement of the optical detectors within the FPA module in a type of two dimensions (8×8) according to an exemplary embodiment of the present disclosure.

As illustrated in FIGS. 5A and 5B, the light detectors within the FPA module according to the exemplary embodiment of the present disclosure may be disposed at different intervals according to arrangement positions thereof. The region in which the light detectors are disposed may be divided into a high resolution region H and a low resolution region L, and an interval between the light detectors disposed in the high resolution region H may be smaller than an interval between the light detectors disposed in the low resolution region L.

That is, in a case where the larger number of pieces of 3-dimensional image information is present at a center portion of a monitoring target or the 3-dimensional image information in a center portion of a monitoring target is more significant, the detectors may be densely disposed at a center portion of the FPA module and the detectors may be sparsely disposed at an outer portion. Through this, a quality of 3-dimensional image data of a desired region may be improved while equally maintaining complexity of the entire readout ICs.

Each light detector 50 may include a light receiving unit 501 for generating an electrical signal by receiving light, and a pad 503 for transferring the generated electrical signal to an external readout IC. A micro lens (not illustrated in the drawing) for improving light efficiency may be further formed on the light receiving unit 501.

In the meantime, in the present exemplary embodiment, the light receiving unit 501 and the pad 503 may be formed on the same surface, and may be formed on opposing surfaces for a backside illumination type implementation.

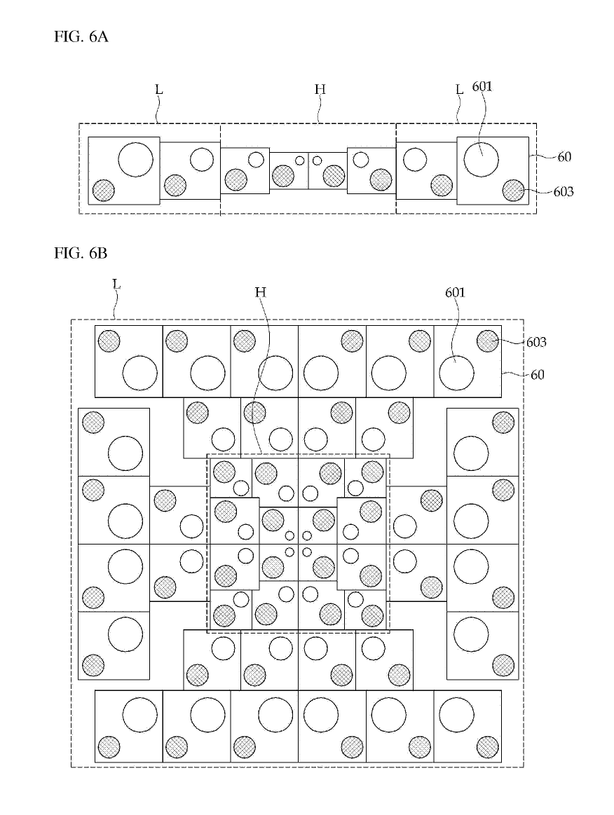

FIG. 6A is a diagram illustrating an arrangement of optical detectors within an FPA module in a type of one dimension (1×8) according to another exemplary embodiment of the present disclosure. FIG. 6B is a diagram illustrating an arrangement of optical detectors within the FPA module in a type of two dimensions (8×8) according to another exemplary embodiment of the present disclosure.

As illustrated in FIGS. 6A and 6B, the light detectors within the FPA module according to another exemplary embodiment of the present disclosure may be arranged at different intervals and have different sizes according to arrangement positions thereof. The region in which the light detectors are disposed may be divided into a high resolution region H and a low resolution region L, and an interval between the light detectors disposed in the high resolution region H may be smaller than an interval between the light detectors disposed in the low resolution region L. As the interval between the light detectors is increased in the low resolution region L, sizes of the light detectors in the low resolution region L may be larger than sizes of the light detectors in the high resolution region H.

That is, in a case where the larger number of pieces of 3-dimensional image information is present at a center portion of a monitoring target or the 3-dimensional image information in a center portion of a monitoring target is more significant, the detectors may be densely disposed at a center portion of the FPA module and the detectors may be sparsely disposed in an outer portion. Through this, a quality of 3-dimensional image data of a desired region may be improved while equally maintaining complexity of the entire readout ICs. The size of the detector may be increased by an area of an increased interval between the detectors in an outer portion of the FPA module, thereby achieving an effect of improving an SNR.

Each light detector 60 may include a light receiving unit 601 for generating an electrical signal by receiving light, and a pad 603 for transferring the generated electrical signal to an external readout IC. A micro lens (not illustrated in the drawing) for improving light efficiency may be further formed on the light receiving unit 601.

In the meantime, in the present exemplary embodiment, the light receiving unit 601 and the pad 603 may be formed on the same surface, and may be formed on opposing surfaces for a backside illumination type implementation.

From the foregoing, it will be appreciated that various embodiments of the present disclosure have been described herein for purposes of illustration, and that various modifications may be made without departing from the scope and spirit of the present disclosure. The exemplary embodiments disclosed in the specification of the present disclosure will not limit the present disclosure. The scope of the present disclosure will be interpreted by the claims below, and it will be construed that all techniques within the scope equivalent thereto belong to the scope of the present disclosure.

What is claimed is:

1. A focal plane array (FPA) module for obtaining a 3-dimensional image for a monitoring target, the FPA module comprising:
a plurality of light detectors configured to detect light reflected from the monitoring target,
wherein the plurality of light detectors is disposed at different intervals according to positions.

2. The FPA module of claim 1, wherein a region in which the plurality of light detectors is disposed is divided into a high resolution region and a low resolution region, and an interval between the light detectors disposed in the high resolution region is smaller than an interval between the light detectors disposed in the low resolution region.

3. The FPA module of claim 1, wherein the light detector comprises:
a light receiving unit configured to generate an electrical signal by receiving light; and
a pad configured to transfer the electrical signal to an external readout IC.

4. The FPA module of claim 3, wherein the light detector further comprises:
a micro lens formed on the light receiving unit.

5. A focal plane array (FPA) module for obtaining a 3-dimensional image for a monitoring target, the FPA module comprising:
a plurality of light detectors configured to detect light reflected from the monitoring target,
wherein the plurality of light detectors has different sizes according to positions.

6. The FPA module of claim 5, wherein a region in which the plurality of light detectors is disposed is divided into a high resolution region and a low resolution region, and the light detectors disposed in the high resolution region are smaller than the light detectors disposed in the low resolution region.

7. The FPA module of claim 5, wherein the light detector further comprises:
a light receiving unit configured to generate an electric signal by receiving light; and
a pad configured to transfer the electric signal to an external readout IC.

8. The FPA module of claim 7, wherein the light detector further comprises:
a micro lens formed on the light receiving unit.
